(19) United States
(12) Patent Application Publication
(10) Pub. No.: US 2020/0098741 A1
(43) Pub. Date: Mar. 26, 2020

(54) ELECTROSTATIC DISCHARGE PROTECTION DEVICE

(71) Applicant: GLOBALFOUNDRIES Singapore Pte. Ltd., Singapore (SG)

(72) Inventor: Jie Zeng, Singapore (SG)

(21) Appl. No.: 16/141,982

(22) Filed: Sep. 26, 2018

(51) Int. Cl. H01L 27/02; H01L 29/08; H01L 29/10

(52) U.S. Cl. CPC H01L 27/0262; H01L 29/0808; H01L 29/1095; H01L 29/1008; H01L 29/0821

(57) ABSTRACT

An ESD Protection Device includes a semiconductor body including a substrate, conductivity regions, and emitter and collector portions. Laterally adjacent first and second conductivity regions are arranged at least partially within the semiconductor body. The emitter and collector portions are disposed in contact with and arranged over the first and second conductivity regions respectively. The third conductivity region is disposed between the second conductivity region and the collector portion. The first and third conductivity regions have a first conductivity type. The second conductivity region, and the emitter and collector portions have a second conductivity type different from the first conductivity type. When an electrostatic discharge level exceeds a predetermined level, a first discharge current passes between the emitter portion and the collector portion through the first and second conductivity regions. A second discharge current subsequently occurs and passes between the first and third conductivity regions through the second conductivity region.

### TECHNICAL FIELD

The present disclosure relates generally to electrostatic discharge (ESD) protection devices.

### BACKGROUND

Bipolar devices, for example npn devices, are commonly used as high voltage ESD protection devices. FIG. 1 shows a cross-sectional view of a prior art ESD protection device 100 in the form of a lateral npn-based ESD protection device. The device 100 includes a p-well having a p-type conductivity (PWELL 102) and two n-wells having an n-type conductivity (NWELL 104, NWELL 106). The PWELL 102, NWELL 104 and NWELL 106 are disposed in a lateral arrangement and spaced apart from each other within a deep well having an n-type conductivity (DNW 108). Emitter portions 110, 112 having an n-type conductivity and a base portion 114 having a p-type conductivity are arranged over the PWELL 102, whereas a collector portion 116, 118 is arranged over each NWELL 104, 106. These emitter, collector, base portions 110, 112, 114, 116, 118, together with the PWELL 102, NWELL 104, NWELL 106 and DNW 108 form an npn transistor. The npn transistor is connected to a point in a circuit and is configured to turn on when the electrostatic discharge level exceeds a predefined level, so as to conduct current away from this point of electrostatic discharge, i.e. to decrease the electrostatic discharge.

Although prior art bipolar ESD protection devices, such as device 100, are capable of conducting current away from the point of electrostatic discharge, they often suffer from problems such as a low second breakdown current (also known as failure current) It2 and high on-resistance Rₒₙ. Such problems worsen if the bipolar ESD protection device is for high voltage applications, but is formed with low cost technology.

### SUMMARY

According to an aspect of the present invention, there is provided an electrostatic discharge (ESD) protection device including: a semiconductor body including a substrate, a first conductivity region arranged at least partially within the semiconductor body, and a second conductivity region arranged at least partially within the semiconductor body. The first conductivity region may be laterally adjacent to the second conductivity region, and an emitter portion may be disposed in contact with the first conductivity region and arranged over the first conductivity region. A collector portion may be disposed in contact with the second conductivity region and arranged over the second conductivity region. A third conductivity region may be disposed between the second conductivity region and the collector portion. The first conductivity region and the third conductivity region may have a first conductivity type, and the second conductivity region, the emitter portion, and the collector portion may have a second conductivity type where the first conductivity type is different from the second conductivity type. The ESD protection device may be configured to where a first discharge current passes between the emitter portion and the collector portion through the first conductivity region and the second conductivity region when an electrostatic discharge level exceeds a predetermined level, and a second discharge current may subsequently occur after the first discharge current. The second discharge current may pass between the first conductivity region and the third conductivity region through the second conductivity region.

With the second discharge current, the second breakdown current It2 of the device can be increased. In other words, at the same second breakdown current It2 level, the footprint of the device can be reduced. The presence of the second discharge current also helps to reduce the on-resistance Rₒₙ of the device and enhance the robustness of the device.

These and other advantages and features of the embodiments herein disclosed, will become apparent through reference to the following description and the accompanying drawings. Furthermore, it is to be understood that the features of the various embodiments described herein are not mutually exclusive and can exist in various combinations and permutations.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. Embodiments of the invention will now be illustrated for the sake of example only with reference to the following drawings, in which:

FIG. 1 shows a cross-sectional view of a prior art ESD protection device;

FIG. 2 shows a cross-sectional view of an ESD protection device according to an embodiment of the present invention;

FIG. 3 shows a cross-sectional view of the device of FIG. 2 when in use;

FIG. 4 shows an equivalent circuit of a segment of the device of FIG. 2;

FIG. 5 shows current-voltage characteristics of the prior art device of FIG. 1 and the device of FIG. 2;

FIG. 6 shows results obtained from modelling the prior art device of FIG. 1 and the device of FIG. 2 in technology computer aided design (TCAD);

FIG. 7 shows transmission line pulse (TLP) measured silicon data of the prior art device of FIG. 1 and the device of FIG. 2;

FIG. 8A-FIG. 8D show TCAD simulated electron and hole current densities for the prior art device of FIG. 1 and the device of FIG. 2;

FIG. 9 shows a cross-sectional view of an ESD protection device according to an alternative embodiment of the present invention;

FIG. 10 shows a cross-sectional view of an ESD protection device according to another alternative embodiment of the present invention;

FIG. 11 shows a cross-sectional view of an ESD protection device according to yet another alternative embodiment of the present invention;

FIG. 12 shows a cross-sectional view of an ESD protection device according to yet another alternative embodiment of the present invention; and

FIG. 13 shows how the current-voltage characteristics and leakage current of the device of FIG. 2 change when a distance within the device changes.

### DETAILED DESCRIPTION

Embodiments generally relate to semiconductor devices. More particularly, some embodiments relate to electrostatic discharge (ESD) protection devices, such as parasitic silicon controlled rectifiers. Such ESD protection devices, for example, may be incorporated into integrated circuits (ICs). The devices or ICs may be incorporated into or used with, for example, consumer electronic products, or related to other types of devices.

According to various non-limiting embodiments, an electrostatic discharge (ESD) protection device may include a semiconductor body including a substrate; a first conductivity region arranged at least partially within the semiconductor body; a second conductivity region arranged at least partially within the semiconductor body; wherein the first conductivity region is laterally adjacent to the second conductivity region; an emitter portion disposed in contact with the first conductivity region and arranged over the first conductivity region; a collector portion disposed in contact with the second conductivity region and arranged over the second conductivity region; and a third conductivity region disposed between the second conductivity region and the collector portion; wherein the first conductivity region and the third conductivity region have a first conductivity type; wherein the second conductivity region, the emitter portion, and the collector portion have a second conductivity type; and wherein the first conductivity type is different from the second conductivity type; and wherein the ESD protection device is configured to where a first discharge current passes between the emitter portion and the collector portion through the first conductivity region and the second conductivity region when an electrostatic discharge level exceeds a predetermined level; and a second discharge current subsequently occurs after the first discharge current and where the second discharge current passes between the first conductivity region and the third conductivity region through the second conductivity region.

According to various non-limiting embodiments, the third conductivity region may include one or more dopants and may include a higher concentration of dopants as compared to the second conductivity region and the collector portion.

According to various non-limiting embodiments, the third conductivity region may be disposed partially within one or both of the second conductivity region and the collector portion.

According to various non-limiting embodiments, the semiconductor body may further include a fourth conductivity region. The fourth conductivity region may be arranged over the substrate, and may include a first portion having the first conductivity type and a second portion having the second conductivity type.

According to various non-limiting embodiments, the first conductivity region and the second conductivity region may be disposed at least partially within the first portion and the second portion of the fourth conductivity region respectively.

According to various non-limiting embodiments, the first portion of the fourth conductivity region may extend laterally away from the first conductivity region towards the second conductivity region.

According to various non-limiting embodiments, the first portion of the fourth conductivity region may be disposed within the second portion of the fourth conductivity region.

According to various non-limiting embodiments, the first portion of the fourth conductivity region may include a high voltage well.

According to various non-limiting embodiments, the second portion of the fourth conductivity region may include a deep well.

According to various non-limiting embodiments, the second portion of the fourth conductivity region may include an epitaxial region and the second conductivity region may be at least partially disposed within the epitaxial region.

According to various non-limiting embodiments, the second portion may further include a buried layer arranged between the epitaxial region and the semiconductor substrate.

According to various non-limiting embodiments, the collector portion may be disposed between the third conductivity region and a collector terminal for electrical connection of the collector portion to an external portion of the device.

According to various non-limiting embodiments, the semiconductor body may include only the substrate. The first conductivity region and the second conductivity region may be at least partially arranged within the substrate.

According to various non-limiting embodiments, the ESD protection device may further include a base portion having the first conductivity type where the base portion contacts the first conductivity region; and a resistance between the emitter portion and the base portion.

According to various non-limiting embodiments, the first conductivity type may be p-type and the second conductivity type may be n-type.

According to various non-limiting embodiments, the first conductivity region may be in contact with the second conductivity region.

According to various non-limiting embodiments, the ESD protection device may further include an isolation region for isolating the emitter portion from the collector portion.

According to various non-limiting embodiments, the third conductivity region may be disposed at least partially within the isolation region.

According to various non-limiting embodiments, the collector portion may be arranged below a surface of the device; and the device may further include a block layer arranged over the surface of the device and the collector portion.

According to various non-limiting embodiments, the block layer may at least partially overlap the collector portion.

Aspects of the present invention and certain features, advantages, and details thereof, are explained more fully below with reference to the non-limiting examples illustrated in the accompanying drawings. Descriptions of well-known materials, fabrication tools, processing techniques, etc., are omitted so as not to unnecessarily obscure the invention in detail. It should be understood, however, that the detailed description and the specific examples, while indicating aspects of the invention, are given by way of illustration only, and are not by way of limitation. Various substitutions, modifications, additions, and/or arrangements, within the spirit and/or scope of the underlying inventive concepts will be apparent to those skilled in the art from this disclosure.

Approximating language, as used herein throughout the specification and claims, may be applied to modify any quantitative representation that could permissibly vary without resulting in a change in the basic function to which it is related. Accordingly, a value modified by a term or terms, such as “about,” is not limited to the precise value specified. In some instances, the approximating language may correspond to the precision of an instrument for measuring the value.

The terminology used herein is for the purpose of describing particular examples only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include (and any form of include, such as “includes” and “including”), and “contain” (and any form of contain, such as “contains” and “containing”) are open-ended linking verbs. As a result, a method or device that “comprises,” “has,” “includes” or “contains” one or more steps or elements possesses those one or more steps or elements, but is not limited to possessing only those one or more steps or elements. Likewise, a step of a method or an element of a device that “comprises,” “has,” “includes” or “contains” one or more features possesses those one or more features, but is not limited to possessing only those one or more features. Furthermore, a device or structure that is configured in a certain way is configured in at least that way, but may also be configured in ways that are not listed.

As used herein, the term “connected,” when used to refer to two physical elements, means a direct connection between the two physical elements. The term “coupled,” however, can mean a direct connection or a connection through one or more intermediary elements.

As used herein, the terms “may” and “may be” indicate a possibility of an occurrence within a set of circumstances; a possession of a specified property, characteristic or function; and/or qualify another verb by expressing one or more of an ability, capability, or possibility associated with the qualified verb. Accordingly, usage of “may” and “may be” indicates that a modified term is apparently appropriate, capable, or suitable for an indicated capacity, function, or usage, while taking into account that in some circumstances the modified term may sometimes not be appropriate, capable or suitable. For example, in some circumstances, an event or capacity can be expected, while in other circumstances the event or capacity cannot occur—this distinction is captured by the terms “may” and “may be.”

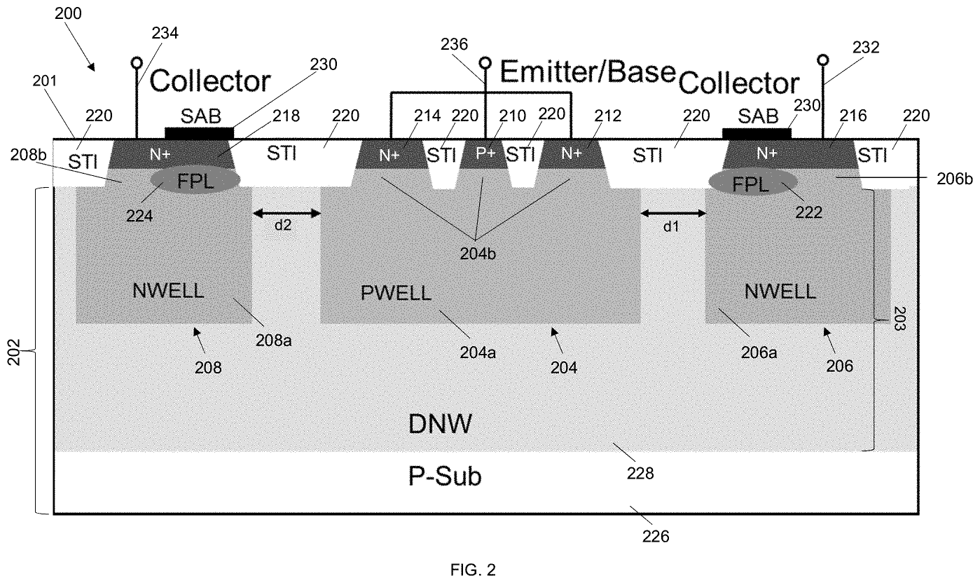

FIG. 2 shows a cross-sectional view of an electrostatic discharge (ESD) protection device 200 according to an embodiment of the present invention. The ESD protection device 200 may be referred to as a parasitic silicon controlled rectifier (SCR).

Referring to FIG. 2, the device 200 may include a semiconductor body 202 having a first conductivity region 204 and a second conductivity region 206/208. The first conductivity region 204 may have a first conductivity type, and the second conductivity region 206/208 may have a second conductivity type that is different from the first conductivity type. In a non-limiting embodiment, the first conductivity region 204 may be a PWELL having a p-type conductivity, and the second conductivity region 206/208 may be a NWELL having an n-type conductivity. The first conductivity region 204, the second conductivity region 206 and the second conductivity region 208 may be laterally arranged at least partially within the semiconductor body 202. The first conductivity region 204 may be laterally adjacent to the second conductivity region 206 and the second conductivity region 208. The first conductivity region 204 may be positioned between the second conductivity region 206 and the second conductivity region 208. In the device 200, the first conductivity region 204, second conductivity region 206 and second conductivity region 208 may be spaced apart from each other. The distance between the first conductivity region 204 and second conductivity region 206, and the distance between the first conductivity region 204 and second conductivity region 208 are denoted as “d1” and “d2” respectively in FIG. 2.

The device 200 may further include a base portion 210 and emitter portions 212, 214 disposed in contact with the first conductivity region 204. The base portion 210 and the first conductivity region 204 may be disposed in a vertical arrangement. Similarly, each of the emitter portions 212, 214 and the first conductivity region 204 may be disposed in a vertical arrangement. Further, a collector portion 216 and a collector portion 218 may be disposed in contact with the second conductivity region 206 and second conductivity region 208 respectively. Each collector portion 216, 218 and the respective second conductivity region 206, 208 may be disposed in a vertical arrangement. For example, as seen in FIG. 2, the base portion 210 and emitter portions 212, 214 may be arranged over the first conductivity region 204, whereas each of the collector portions 216, 218 may be arranged over the respective second conductivity region 206, 208. The base portion 210 may have a p-type conductivity in a non-limiting embodiment; whereas, the emitter portions 212, 214 and the collector portions 216, 218 may have an n-type conductivity.

The first conductivity region 204 may extend vertically away from the surface 201 of the device 200 (in other words, away from the emitter and base portions 210, 212, 214), i.e. into the semiconductor body 202. Similarly, the second conductivity region 206 and second conductivity region 208 may extend vertically away from the surface 201 of the device 200 (in other words, away from the respective collector portions 216, 218). The depths of the first conductivity region 204, second conductivity region 206 and second conductivity region 208 (i.e. the amount the first conductivity region 204, second conductivity region 206, second conductivity region 208 may extend vertically away from the base, collector, emitter portions 210, 212, 214, 216, 218) may be substantially the same in a non-limiting embodiment; alternatively each conductivity region 204, 206, 208 may have a different depth from the other conductivity regions 204, 206, and 208.

As shown in FIG. 2, the first conductivity region 204 may include a first portion 204a having a substantially rectangular cross-section and a second portion 204b having a plurality of castellations in contact with the first portion 204a in a non-limiting embodiment; however, the plurality of castellations may be formed having a rectangular or square shape in an alternative embodiment. The first and second portions 204a, 204b may be disposed in a vertical arrangement (e.g., as seen in FIG. 2, the second portion 204b may be arranged over the first portion 204a in a non-limiting embodiment). The castellations may be laterally arranged and spaced apart from one another. Each of the base and emitter portions 210, 212, 214 may be disposed on a respective castellation of the first conductivity region 204, with the base portion 210 positioned between the emitter portions 212, 214. Similarly, each second conductivity region 206, 208 may include a first portion 206a, 208a having a rectangular cross-section and a second portion 206b, 208b having a castellation in contact with the first portion 206a, 208a. The castellation and the first portion 206a, 208a may be disposed in a vertical arrangement (e.g., as seen in FIG. 2, the castellation of each second conductivity region 206, 208 may be arranged over the first portion 206a, 208a of the second conductivity region 206, 208). Each collector portion 216, 218 may be disposed on the castellation of the respective second conductivity region 206, 208. The castellations of the first conductivity region 204, second conductivity region 206, second conductivity region 208 may each have a trapezoidal cross-section. Similarly, the base, emitter and collector portions 210, 212, 214, 216, 218 may each have a trapezoidal cross-section and may be sized such that each of these portions 210, 212, 214, 216, 218, together with the respective castellation the portion 210, 212, 214, 216, 218 is disposed on, forms a tapered structure (with a trapezoidal cross-section) in a non-limiting embodiment. The tapered structures may taper away from the first portions 204a, 206a, 208a of the first conductivity region 204, second conductivity region 206 and second conductivity region 208. In addition, the tapered structures may be laterally arranged and spaced apart from one another.

The device 200 may further include one or more third conductivity regions 222/224 having a conductivity type that is the same as the first conductivity region 204, e.g. p-type conductivity when the first conductivity region 204 has a p-type conductivity, where the third conductivity region 222/224 may be in the form of floating conductivity-type layers 222/224 (e.g. floating p-type layers in a non-limiting embodiment). The third conductivity region 222 may be disposed between the second conductivity region 206 (e.g., the castellation of the second conductivity region 206) and the collector portion 216, in other words, may be disposed under the collector portion 216 as shown in FIG. 2; whereas, the third conductivity region 224 may be disposed between the second conductivity region 208 (e.g., the castellation of the second conductivity region 208) and the collector portion 218, in other words, may be disposed under the collector portion 218 as shown in FIG. 2. Furthermore, each third conductivity region 222, 224 may extend at least partially across the contact surface between the second conductivity regions 206, 208 and the respective collector portion 216, 218, so that at least a part of the second conductivity regions 206, 208 is in contact with the collector portion 216, 218. In other words, the third conductivity regions 222, 224 may be narrower than its respective second conductivity region 206, 208 and narrower than its respective collector portion 216, 218 in a non-limiting embodiment.

Isolation regions 220 in the form of shallow trench isolation regions (STI) may be disposed in the spaces between the tapered structures (e.g. 210, 212, 214, 216, and 218). Each third conductivity region 222, 224 may be disposed partially within the respective second conductivity region 206, 208, partially within the respective collector portion 216, 218 and also partially within an isolation region 220. In other words, each third conductivity region 222, 224 may be encapsulated by a structure including the isolation region 220 in contact with the third conductivity region 222, 224, the respective second conductivity region 206, 208 and the respective collector portion 216, 218. Each third conductivity region 222, 224 may thus be a buried region which requires minimal additional lateral or vertical space, allowing the size of the device 200 to be reduced. The isolation regions 220 may isolate the emitter portions 212, 214 from the collector portions 216, 218, and from the base portion 210. The isolation regions 220 may also help to isolate the emitter portions 212, 214 from the third conductivity regions 222, 224. Such isolation may help to reduce the amount of interference between the base, emitter and collector portions 210, 212, 214, 216, 218 and between the emitter portions 212, 214 and the third conductivity regions 222, 224.

The isolation regions 220 may include an isolation material, such as but not limited to a gap fill oxide or nitride, or a combination of both. Each isolation region 220 may have a width ranging from about 0.1 um to about 10 um in a non-limiting embodiment, but the width of each isolation region 220 is not limited to this range.

The semiconductor body 202 may include a substrate 226 and a fourth conductivity region 203. In a non-limiting embodiment, the substrate 226 may be a p-type substrate, i.e. having a p-type conductivity, and the fourth conductivity region 203 may have an n-type conductivity in contact with the substrate 226. The fourth conductivity region 203 and the substrate 226 may be disposed in a vertical arrangement (e.g., as seen in FIG. 2, the fourth conductivity region 203 may be arranged over the substrate 226). The fourth conductivity region 203 may include a deep well 228, and the deep well 228 may have an n-type conductivity in a non-limiting embodiment, e.g. a deep NWELL which may extend at least partially across a surface of the substrate 226. The deep well 228 may enable the device 200 for high voltage applications. The first portions 204a, 206a, 208a of the first conductivity region 204, second conductivity region 206 and second conductivity region 208 may be disposed within the deep well 228. The isolation region 220 between the first conductivity region 204 and respective second conductivity regions 206, 208 may be in contact with the deep well 228.

In a non-limiting embodiment, the substrate 226 may include any silicon-containing substrate including, but not limited to, silicon (Si), single crystal silicon, polycrystalline Si, amorphous Si, silicon-on-sapphire (SOS), silicon-on-insulator (SOI) or silicon-on-replacement insulator (SRI) or silicon germanium substrates and the like. Substrate 226 may in addition or instead include various isolations, dopings and/or device features. The substrate 226 may include other suitable elementary semiconductors, such as, for example, germanium (Ge) in crystal, a compound semiconductor, such as silicon carbide (SiC), gallium arsenide (GaAs), gallium phosphide (GaP), indium phosphide (InP), indium arsenide (InAs), and/or indium antimonide (InSb) or combinations thereof an alloy semiconductor including GaAsP, AlInAs, GaInAs, GaInP, or GaInAsP or combinations thereof.

In another non-limiting embodiment, the device 200 may be conventionally fabricated, for example, using known processes and techniques (e.g., growing epitaxial material and implanting impurities). In one example, the implant material for the emitter portions 212, 214, the collector portions 216, 218, may be the same implant material, for example implanting phosphorus. For example, the p-type material may be or include, but is not limited to boron doped silicon as a material, and/or the n-type material may be or include, but is not limited to doped silicon material including phosphorus dopants, arsenic dopants, or combinations thereof.

As shown in FIG. 2, the semiconductor body 202, conductivity regions (204, 206, 208, 222, 224), isolation regions 220 and portions (base, emitter, collector portions 210, 212, 214, 216, 218) described above may be arranged below the surface 201 of the device 200. The device 200 may optionally further include block layers 230 in the form of salicide block layers (SAB) arranged over the surface 201 of the device 200. The block layers 230 may be formed of silicon nitride. Each block layer 230 and a collector portion 216, 218 may be arranged in a vertical arrangement (e.g., as seen in FIG. 2, each block layer 230 may be arranged over the collector portion 216, 218). Each block layer 230 may at least partially overlap with the respective collector portion 216, 218. A silicide layer having high conductivity may be grown on the surface 201 of the device 200. The block layers 230 may prevent the silicide from growing on the portions of the surface 201 beneath the block layers 230. By having the block layers 230 partially overlap the respective collector portions 216, 218, the silicide layer can help guide external current flow (current flow from external of the device 200 e.g. from other parts of the circuit) to the collector portions 216, 218, and this may improve the performance of the device 200.

The base, emitter and collector portions 210, 212, 214, 216, 218, or combinations thereof may include one or more dopants and may have the same doping concentrations (i.e. same concentration of dopants) or different doping concentrations (i.e. different concentrations of dopants) from each other. The first conductivity region 204, second conductivity region 206 and second conductivity region 208 may also include one or more dopants and may also be of the same doping concentration, but different from that of the base, emitter and collector portions 210, 212, 214, 216, 218. The third conductivity region 222, 224 may also include one or more dopants and may be more heavily doped (i.e. include a higher concentration of dopants) as compared to the base, emitter and collector portions 210, 212, 214, 216, 218. Heavily doping the third conductivity region 222, 224 can help to provide a high second breakdown current (It2). The base, emitter and collector portions 210, 212, 214, 216, 218 may be more heavily doped than the first conductivity region 204, second conductivity region 206 and second conductivity region 208, which may in turn be more heavily doped than the deep well 228. Further, the deep well 228 may be more heavily doped than the substrate 226. In one non-limiting example, the doping concentrations of the base portion 210, the emitter portions 212, 214, the collector portions 216, 218, the first conductivity region 204, the second conductivity regions 206, 208, the third conductivity regions 222, 224, the deep well 228 and the substrate 226 may range from about 1E15 cm⁻³ to about 1E20 cm⁻³. For example, the doping concentrations of the base portion 210, the emitter portion 212, the emitter portion 214, the collector portion 216, the collector portion 218, the first conductivity region 204, the second conductivity region 206, the second conductivity region 208, the third conductivity region 222, the third conductivity region 224, the deep well 228 and the substrate 226 may be respectively, about 1E20 cm⁻³, about 1E20 cm⁻³, about 1E20 cm⁻³, about 1E20 cm⁻³, about 1E20 cm⁻³, about 2E17 cm⁻³, about 2E17 cm⁻³, about 2E17 cm⁻³, about 5E18 cm⁻³, about 5E18 cm⁻³, about 1E16 cm⁻³, about 1E15 cm⁻³.

Together, each collector portion 216, 218, the respective second conductivity region 206, 208, third conductivity region 222, 224 and block layer 230 may form a collector region. The base and emitter portions 210, 212, 214, together with the first conductivity region 204, may form an emitter/base region. Although not shown in FIG. 2, the device 200 may further include metal elements exposed above the surface 201 of the device 200 and above the base, emitter and collector portions 210, 212, 214, 216, 218. The metal element above the collector portion 216 may be coupled to a collector terminal 232, the metal element above with the collector portion 218 may be coupled to a collector terminal 234, and the metal elements above the base portion 210 and the emitter portions 212, 214 may be coupled to an emitter/base terminal 236. These metal elements together with the collector terminals 232, 234 and emitter/base terminal 236 may be for electrical connection of the collector portions 216, 218 and the base and emitter portions 210, 212, 214 (and therefore, the collector and emitter/base regions) to external portions of the device 200, for example other parts of a circuit, such as a point of electrostatic discharge. The collector portions 216, 218 may be disposed between the respective third conductivity regions 222, 224 and the respective collector terminal 232, 234. This may allow the device 200 to have a higher holding voltage.

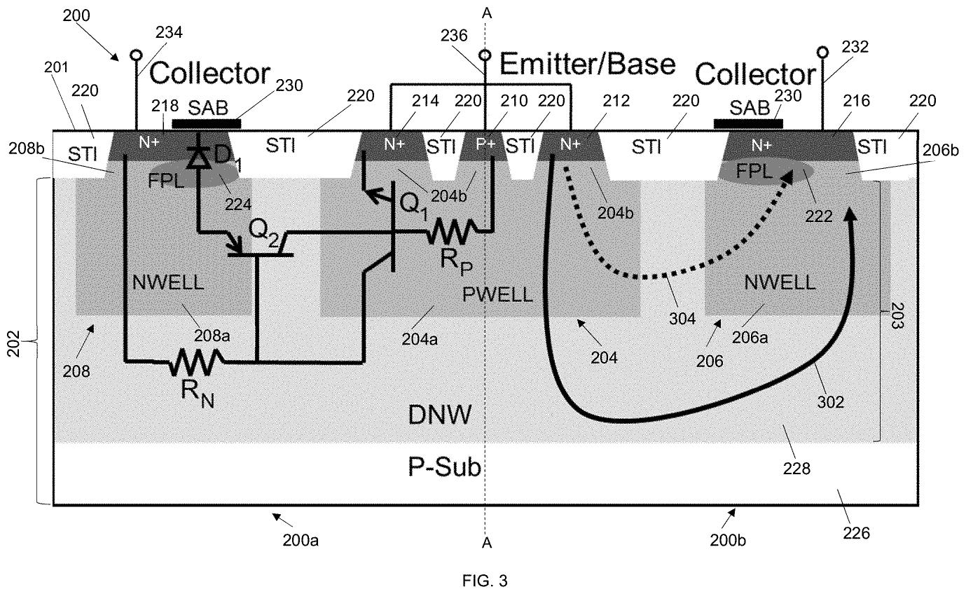

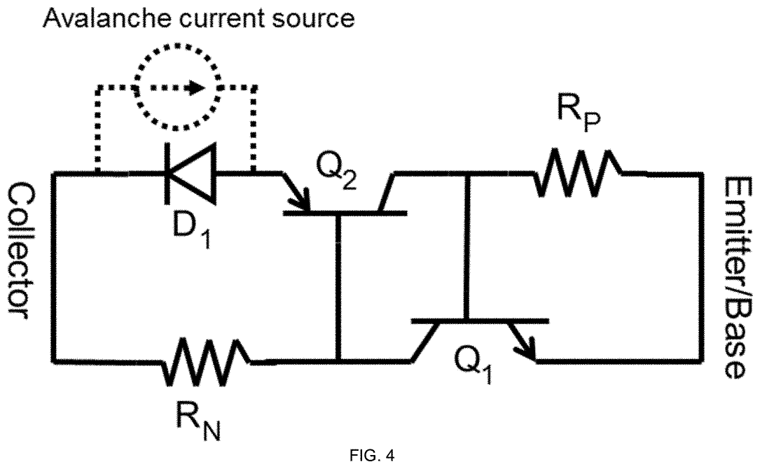

FIG. 3 shows a cross-sectional view of the device 200 when the device 200 is in use. In particular, FIG. 3 shows an equivalent circuit of a first segment 200a of the device 200 and the current flows through a second segment 200b of the device 200. In a non-limiting embodiment, the first and second segments 200a, 200b of the device 200 may be substantially symmetrical (e.g. symmetrical mirror) images of each other about a vertical axis A-A through the middle of the device 200. Similarly, current flows through the first and second segments 200a, 200b of the device 200 may occur in the first segment 200a and the second segment 200b in a symmetrical manner about the vertical axis A-A through the middle of the device 200. FIG. 4 shows the equivalent circuit of FIG. 3 with an avalanche current source. This avalanche current source may be present when a current density level caused by an ESD event exceeds a pre-determined level, such as but not limited to a pre-determined level over 1E5 A/cm², alternatively a pre-determined level ranging from about 5E4 A/cm² to about 5E5 A/cm².

The equivalent circuit of FIG. 3 and FIG. 4 may include a first transistor in the form of an npn transistor Q₁ and a second transistor in the form of a pnp transistor Q₂. The npn transistor Q₁ may include the first conductivity region 204 as its base, the emitter portion 214 as its emitter and the deep well 228 as its collector. The pnp transistor Q₂ may include the deep well 228 as its base, the third conductivity region 224 as its emitter and the first conductivity 204 as its collector. The equivalent circuit may also include resistors Rₚ and R_{N} corresponding to the resistance of the first conductivity region 204 and the deep well 228 respectively. In addition, the equivalent circuit may include a diode D₁ corresponding to the p-n junction between the third conductivity region 224 and the collector portion 218. In the equivalent circuit, the base of Q₂ may be electrically connected to the collector of Q₁, and the base of Q₁ may be electrically connected to the collector of Q₂. The resistor Rₚ may be electrically connected between the emitter and base of Q₁ (and thus, between the emitter of Q₁ and collector of Q₂). The resistor R_{N} may be electrically connected between the collector of Q₁ (and thus, the base of Q₂) and the diode D₁.

In use, the emitter and base portions 210, 212, 214 may be shorted to a common voltage and the collector portions 216, 218 may be electrically connected to the point of electrical discharge. When the electrical discharge level exceeds a predetermined level, the reverse voltage between the base portion 210 and each collector portion 216, 218 increases above a breakdown level, causing the junction between the first conductivity region 204 and the deep well 228 to break down and the first transistors Q₁ to turn on. First discharge currents 302 may then pass from the emitter portion 212 to the collector portion 216 through the first conductivity region 204, deep well 228, and second conductivity region 206, and from the emitter portion 214 to the collector portion 218 through the first conductivity region 204, deep well 228 and second conductivity region 208 (the latter not shown in FIG. 3). The avalanche injection from the first discharge currents 302 may cause the second transistors Q₂ to turn on. Second discharge currents 304 may subsequently occur after the first discharge currents 302. The second discharge currents 304 may pass from the first conductivity region 204 to the third conductivity region 222 and finally to the collector region 216 through the deep well 228 and second conductivity region 206, and from the first conductivity region 204 to the third conductivity region 224 and finally to the collector region 218 through the deep well 228 and second conductivity region 208 (the latter not shown in FIG. 3). It is worth noting that ‘first discharge current’ and ‘second discharge current’ are not used herein to describe one current occurring right after the other; although, the second discharge current may occur after the ‘first discharge current’. Such terms are used to distinguish the direction for the two currents, i.e. the first discharge current flows a certain direction along a particular path that is different from the direction and path of the second discharge current.

The device 200 may be considered fully turned on when the transistors Q₁ and Q₂ are all turned on, or in other words, when both the first and second discharge currents 302, 304 flow through the device 200. The first and second discharge currents 302, 304 may be respectively referred to as the first and second snapback currents. The second discharge currents 304 can enhance the robustness and reduce the on-resistance of the device 200. Furthermore, a higher second breakdown current It2 can be achieved or in other words, a smaller footprint at the same It2 level can be obtained.

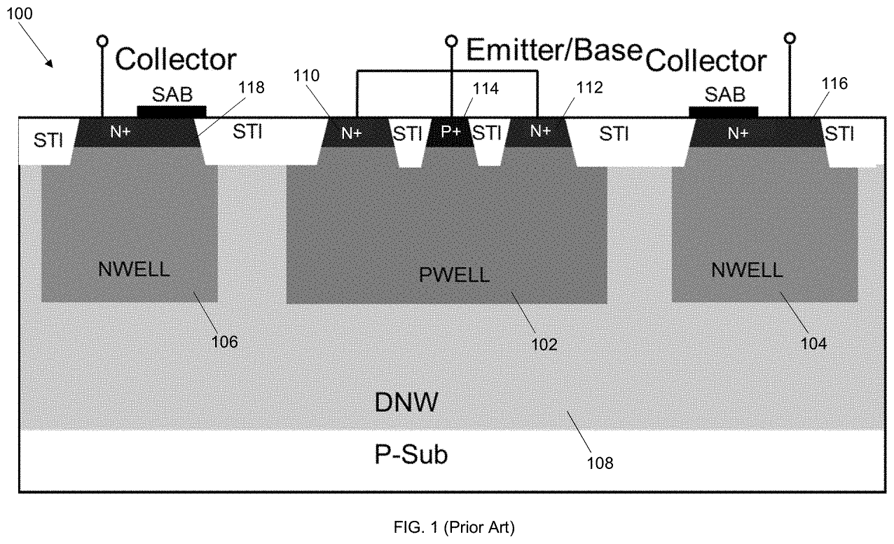

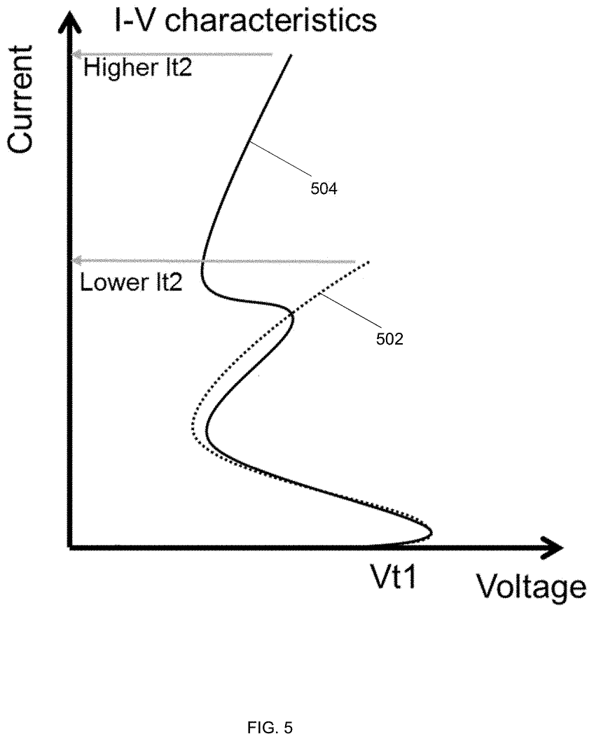

FIG. 5 shows the current-voltage (I-V) characteristics of the prior art device 100 (shown in FIG. 1) and the device 200. In FIG. 5, the plots 502, 504 represent the I-V characteristics of the prior art device 100 and the device 200 respectively. More specifically, the plots 502, 504 are plots of the currents through the devices 100, 200 against the electrostatic discharge voltage applied to the devices 100, 200. As shown in FIG. 5, the breakdown voltage Vt1 of devices 100 and 200 are similar but the second breakdown current It2 of the device 200 is higher than that of the prior art device 100.

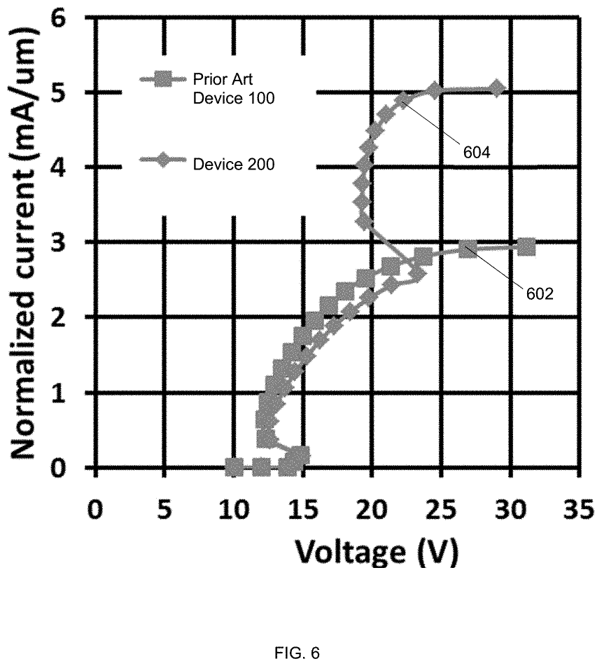

FIG. 6 shows results obtained from modelling the prior art device 100 and the device 200 in technology computer aided design (TCAD). In particular, FIG. 6 shows plots 602, 604 of the normalized currents through the devices 100 and 200 respectively against the electrostatic discharge voltages applied to these devices 100, 200.

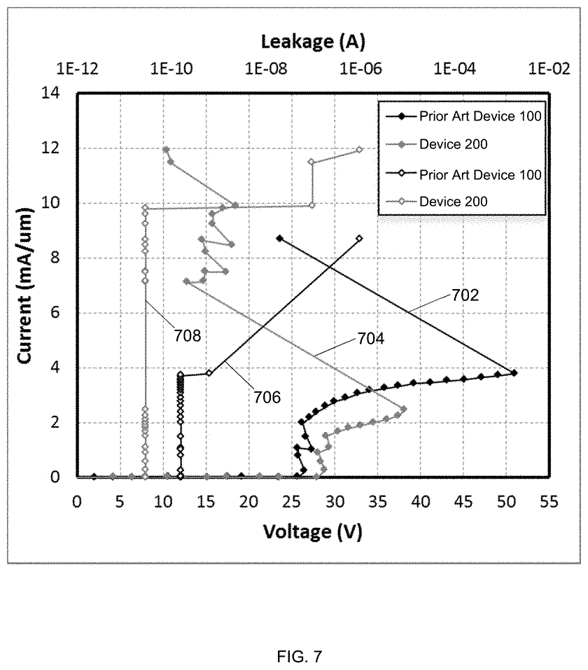

FIG. 7 shows the transmission line pulse (TLP) measured silicon data of the prior art device 100 and the device 200. In particular, FIG. 7 shows plots 702, 704 of the currents through the devices 100 and 200 respectively against the electrostatic discharge voltage applied to these devices 100, 200. FIG. 7 further shows plots 706, 708 of the leakage currents of the devices 100 and 200 respectively. Table 1 below tabulates the results obtained from the TCAD and from the TLP measured silicon data.

TABLE 1

| | | It2 | Second snapback |
|---|---|---|---|
| | | (mA/μm) | present? |
| TCAD results | Device 200 | 5.1 | Yes |
| | Prior art device 100 | 2.9 | No |
| TLP measured | Device 200 | 9.8 | Yes |
| silicon data | Prior art device 100 | 3.8 | No |

As shown in FIG. 5, FIG. 6, FIG. 7 and Table 1, and based on the TCAD results, there is an approximately 1.7 times improvement in the second breakdown current It2 in the device 200 as compared to the prior art device 100; in addition, based on the TLP measured silicon data, there is an approximately 2.6 times improvement in the second breakdown current It2 in the device 200 as compared to the prior art device 100. Further, based on the TLP measured silicon data, the leakage current of the device 200 is lower than the leakage current of the prior art device 100.

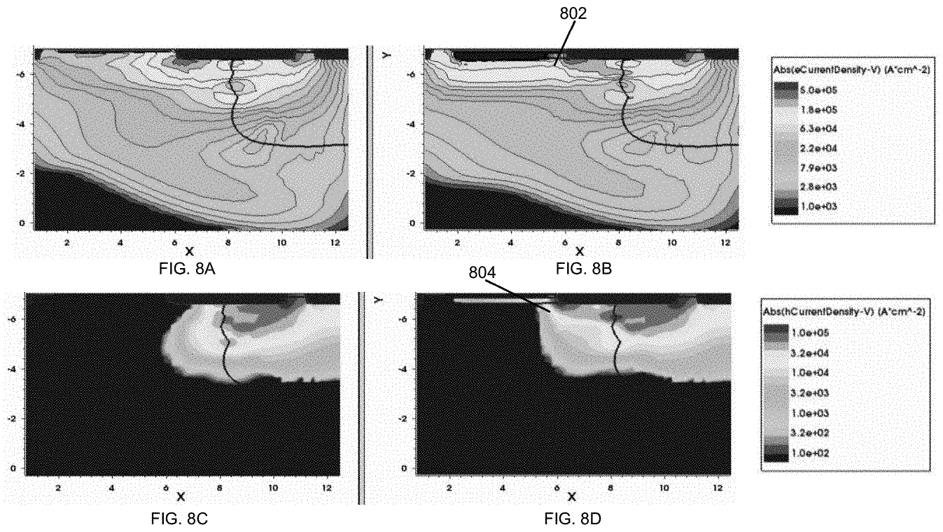

FIG. 8A-FIG. 8D show TCAD simulated electron and hole current densities for the prior art device 100 and device 200 after these devices 100, 200 are fully turned on. In particular, FIG. 8A and FIG. 8B show the electron current density for the devices 100 and 200 respectively, whereas FIG. 8C and FIG. 8D show the hole current density for the devices 100 and 200 respectively. As shown in FIG. 8A-FIG. 8D, as compared to the prior art device 100, there are clear electron and hole current density gradients at the right hand side of the third conductivity region 222 of the device 200. In particular, intensive contours of electron current density 802 and hole current density gradients 804 are present. These represent electron and hole diffusion movements, indicating that the transistor Q₂ is turned on in the device 200. The second snapback current through the transistor Q₂ allows the device 200 to have an improved It2. Thus, the turning on of both the transistors Q₁ and Q₂ allows the device 200 to perform as an effective SCR.

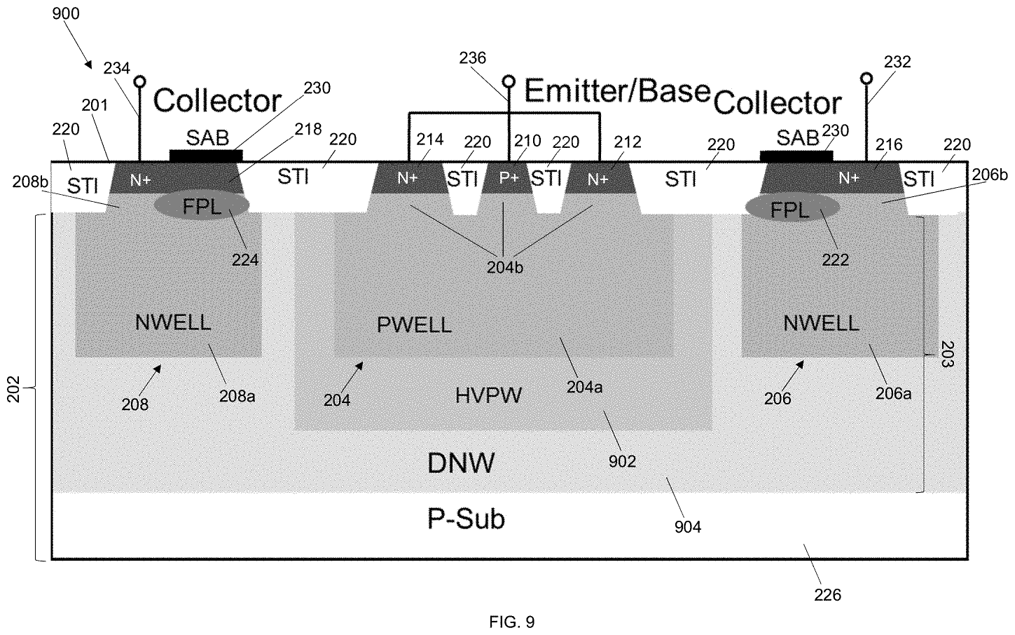

FIG. 9 shows a cross-sectional view of an ESD protection device 900 according to an alternative embodiment of the present invention. The device 900 is similar to the device 200, so the same parts will have the same reference numerals. As shown in FIG. 9, in contrast to the device 200, the fourth conductivity region 203 of the device 900 may include a first portion having a first conductivity type (e.g. p-type conductivity) in the form of a high voltage well 902 (e.g. a high voltage p-well HVPW in a non-limiting embodiment) and a second portion having an second conductivity type (e.g. n-type conductivity) in the form of a deep well 904 (e.g. a deep N-well in a non-limiting embodiment). The high voltage well 902 may be disposed within the deep well 904. The first conductivity region 204 may be disposed partially within the high voltage well 902. The first conductivity region 204 may be more heavily doped than the high voltage well 902, which may in turn be more heavily doped than the deep well 904. The deep well 904 may be more heavily doped than the substrate 226. In one example, the doping concentrations of the high voltage well 902 and the deep well 904 may be about 4E16 cm⁻³ and about 1E16 cm⁻³, respectively. The second conductivity region 206 and second conductivity region 208 may be disposed partially within the deep well 904. The high voltage well 902 may extend laterally away from the first conductivity region 204 towards the second conductivity regions 206, 208, and may be spaced apart from the second conductivity regions 206, 208. The lateral extension of the high voltage well 902 may help to increase the breakdown voltage and holding voltage of the device 900 for high voltage applications. The device 900 may operate similarly to the device 200. In particular, the first discharge currents may flow between the emitter portions 212, 214 and respective collector portions 216, 218 through the first conductivity region 204, high voltage well 902, deep well 904 and respective second conductivity regions 206, 208. The second discharge currents, which may subsequently occur after the first discharge currents, may flow between the first conductivity region 204 and the respective third conductivity region 222, 224 (and finally to the respective collector portion 216, 218) through the high voltage well 902, deep well 904 and respective second conductivity regions 206, 208.

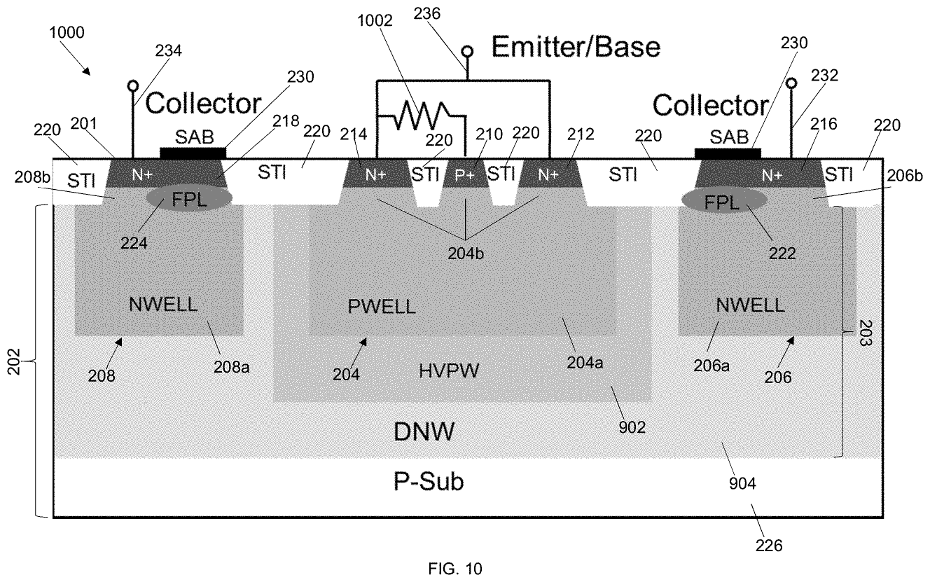

FIG. 10 shows a cross-sectional view of an ESD protection device 1000 according to another alternative embodiment of the present invention. The device 1000 is similar to the device 900, so the same parts will have the same reference numerals. As shown in FIG. 10, as compared to the device 900, the device 1000 may further include resistance in the form of a resistor 1002 between the emitter portion 214 and the base portion 210. The equivalent circuit of the device 1000 is similar to that of the device 200 (shown in FIG. 3 and FIG. 4), except for the addition of resistor 1002 between the emitter of the transistor Q₁ and the resistor Rₚ. The additional resistor 1002 helps to increase the base potential of the transistor Q₁ and therefore, helps to turn on the transistor Q₁ faster when the electrostatic discharge level exceeds the predetermined level for electrostatic discharge. In another alternative embodiment, the resistor 1002 may be electrically connected between the emitter portion 212 and the base portion 210. The base portion 210 may be connected to the emitter portion 212 through the resistor 1002. These alternative embodiments (including device 1000) with the additional resistor operate similarly to the device 900.

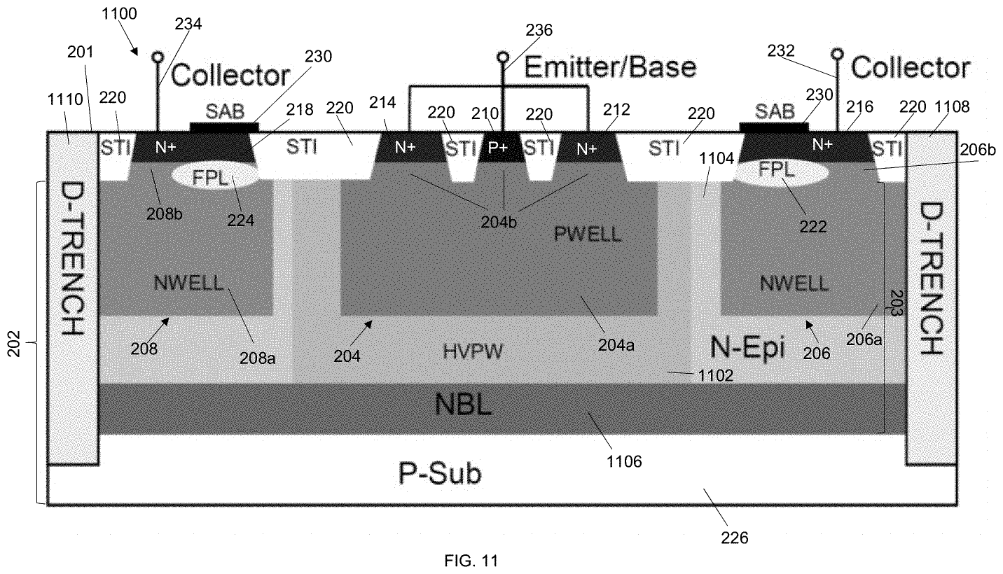

FIG. 11 shows a cross-sectional view of an ESD protection device 1100 according to yet another alternative embodiment of the present invention. The device 1100 is similar to the device 900, so the same parts will have the same reference numerals. The fourth conductivity region 203 of the device 1100 may also include a first portion having a first conductivity type and a second portion having a second conductivity type. However, in the device 1100, while the first portion of the fourth conductivity region 203 may also include a high voltage well 1102 similar to the device 900, the second portion of the fourth conductivity region 203 may include an epitaxial region 1104 (e.g. N-Epitaxial region in a non-limiting embodiment) and a buried layer (e.g. an N-buried layer 1106 in a non-limiting embodiment). The first conductivity region 204 may be disposed partially within the high voltage well 1102, and the second conductivity regions 206, 208 may be partially disposed within the epitaxial region 1104. Similar to the high voltage well 902, the high voltage well 1102 may also extend laterally away from the first conductivity region 204 towards the second conductivity regions 206, 208. The high voltage well 1102 may be disposed within the epitaxial region 1104 and may be spaced apart from the second conductivity regions 206, 208. The buried layer 1106 and the epitaxial region 1104 may be disposed in a vertical arrangement. In particular, the buried layer 1106 may be arranged between the epitaxial region 1104 and the substrate 226 to isolate the epitaxial region 1104 from the substrate 226 to reduce interference from the substrate 226. The first conductivity region 204 may also be more heavily doped than the high voltage well 1102. The high voltage well 1102 and the epitaxial region 1104 may be more lightly doped than the buried layer 1106, which may in turn be more heavily doped than the substrate 226. In one example, the doping concentrations of the high voltage well 1102, the epitaxial region 1104 and the buried layer 1106 may be about 4E16 cm⁻³, about 1E16 cm⁻³ and about 1E18 cm⁻³, respectively. The device 1100 may further include isolation elements in the form of deep trenches 1108, 1110 each having an elongate structure and arranged along a side of the device 1100. Deep trench 1108 and deep trench 1110 may extend vertically away from the surface of the device 1100 towards the substrate 226 and may further extend partially into the substrate 226. Together, the buried layer 1106, the deep trench 1108 and the deep trench 1110 may form an isolation structure for isolating the regions (first conductivity region 204, second conductivity regions 206, 208, third conductivity regions 222, 224, isolation regions 220) and portions (base, emitter, collector portions 210, 212, 214, 216, 218) from the substrate 226 and from the external environment. Therefore, external interference from for example, other devices near the device 1100, can be reduced. The device 1100 may operate similarly to the devices 200, 900. In particular, first discharge currents may flow between the emitter portions 212, 214 and the respective collector portions 216, 218 through the first conductivity region 204, high voltage well 1102, epitaxial region 1104 and respective second conductivity regions 206, 208. Second discharge currents may subsequently occur after the first discharge currents and may flow between the first conductivity region 204 and the respective third conductivity regions 222, 224 (and finally to the respective collector portions 216, 218) through the high voltage well 1102, epitaxial region 1104 and respective second conductivity regions 206, 208.

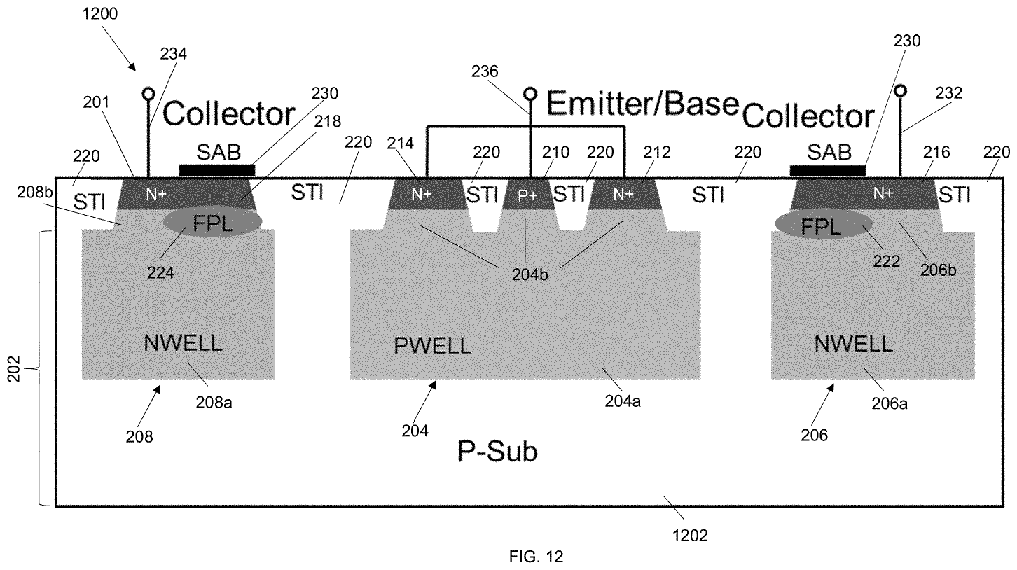

FIG. 12 shows a cross-sectional view of an ESD protection device 1200 according to yet another alternative embodiment of the present invention. The device 1200 is similar to the device 200, and thus, the same parts will have the same reference numerals. As shown in FIG. 12, as compared to the device 200, the semiconductor body 202 of the device 1200 may include only a substrate 1202 where the first conductivity region 204 and the second conductivity region 206/208 are at least partially arranged in the substrate 1202. The substrate 1202 may have a first conductivity type, e.g. p-type conductivity, in a non-limiting embodiment. The first conductivity region 204, second conductivity region 206, second conductivity region 208 (in particular, their first portions 204a, 206a, 208a) may be disposed partially within the substrate 1202. This simplifies the manufacturing process and thus, helps reduce manufacturing costs. The device 1200 may operate similarly to the device 200. In particular, first discharge currents may flow between the emitter portions 212, 214 and the respective collector portions 216, 218 through the first conductivity region 204, the substrate 1202 and the respective second conductivity regions 206, 208. Second discharge currents may subsequently occur after the first discharge currents and may flow between the first conductivity region 204 and the respective third conductivity regions 222, 224 (and finally to the respective collector portions 216, 218) through the substrate 1202 and the respective second conductivity regions 206, 208.

Various modifications can be made to the device 200 described above. Similar modifications as those described with reference to device 200 may be made to devices 900, 1000, 1100, 1200.

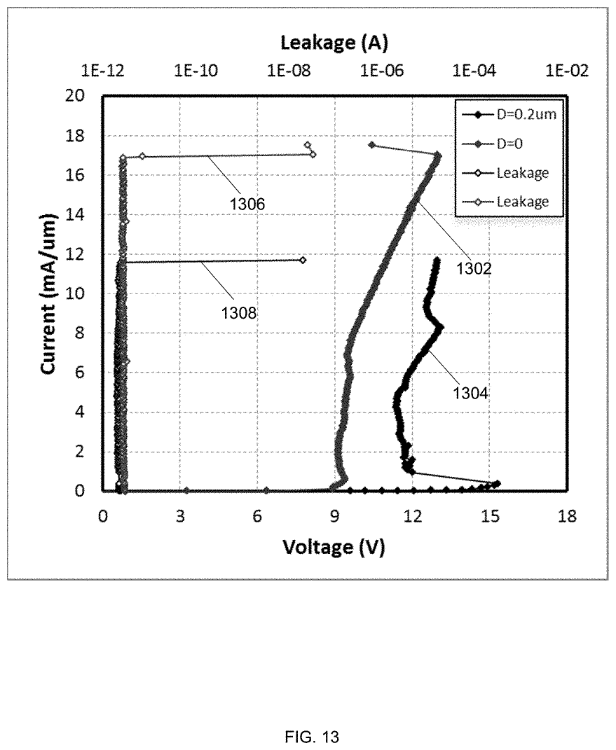

For example, the distances between the first conductivity region 204 and the respective second conductivity regions 206, 208 (denoted as “d1” and “d2” in FIG. 3) may be varied. By varying these distances, the breakdown voltage of the device 200 can be adjusted to a desired level. In device 200, d1 may be the same as d2 and/or may be equal to D, and FIG. 13 shows how the I-V characteristics and leakage current of the device 200 change when D changes. In particular, FIG. 13 shows plots 1302, 1304 of the current through the device 200 against the electrostatic discharge voltage applied to the device 200 when D=0 um (i.e. when the first conductivity region 204 is in contact with the second conductivity region 206 and the second conductivity region 208) and when D=0.2 um respectively. FIG. 13 further shows plots 1306, 1308 of the leakage current of the device 200 when D=0 um and D=0.2 um respectively. As shown in FIG. 13, by reducing the distances d1, d2, the breakdown voltage of the device 200 can be reduced. Reducing the distances d1, d2 can also reduce the voltage gap between the breakdown voltage and the holding voltage of the device 200. In addition, the second breakdown current It2 of the device 200 can be further increased by reducing the distances d1, d2. In particular, the second breakdown current It2 of the device 200 can be further increased to approximately 17 mA/um when D=0 um. Therefore, reducing the distances between the first conductivity region 204 and the respective second conductivity region 206, 208 can optimize the performance of the device 200.

Further, the characteristics of the third conductivity region(s) 222, 224 may be varied. For example, the doping level of the dopants within each third conductivity region 222, 224 may range from 1E18 cm⁻³ in a non-limiting embodiment to 1E21 cm⁻³. Furthermore, the third conductivity region 222, 224 may be in the form of a buried implantation layer (such as an ESD layer) or a highly doped well, such as a highly doped P-well (e.g. a Pbody or a Zener layer) in a non-limiting embodiment. In addition, the doping levels of the various regions and portions of the device 200 may be varied.

Further, the device 200 may be modified such that all regions and portions having a p-type conductivity (first conductivity type) may be replaced with respective regions and portions having an n-type conductivity (second conductivity type), and all regions and portions having an n-type conductivity may be replaced with respective regions and portions having a p-type conductivity. In other words, the device 200 may be modified to reverse the conductivity types of all the regions and portions. The device 200 may also be modified such that only some regions and portions are replaced with respective regions and portions of an opposite conductivity type. For instance, the substrate 226 can be replaced with an n-type substrate, while the conductivity type of the rest of the device 200 remains the same. It would be clear to a person skilled in the art that the directions of current flows will change accordingly when the conductivity types of the various regions and portions are reversed.

In a non-limiting example, the first conductivity region 204 may have an n-type conductivity, the second conductivity regions 206/208 may have a p-type conductivity, and the third conductivity region may have an n-type conductivity. The various emitter, base, and collector portions 210, 212, 214, 216, 218 may also have opposite conductivity types from that described in the above embodiments. Further, the substrate 226, and the deep well 228 may have an n-type conductivity, and a p-type conductivity, respectively. Such an example illustrates how the various regions may have opposite conductivity types than that described above. In this instance, the first discharge current 302 would flow from the collector portion 216 to the emitter portion 212 through the second conductivity region 206, the optional deep well 228, and through the first conductivity region 204; the same would happen on the other side of the device, i.e. the first discharge current would flow from the collector portion 218 to the emitter portion 214 through the second conductivity region 208, the optional deep well 228, and through the first conductivity region 204. Said differently, the first discharge current 302 would flow in the opposite direction for this non-limiting example than what is depicted in FIG. 3, above. The second discharge current 304 would also flow in the opposite direction for this non-limiting example than what is depicted in FIG. 3, above. The second discharge current may pass from the third conductivity region 222 to the first conductivity region 204 through the second conductivity region 206 and the optional deep well 228, and from the third conductivity region 224 to the first conductivity region 204 through the second conductivity region 208 and the optional deep well 228. In other words, regardless of the conductivity types of the regions and portions, the first discharge currents may pass between the emitter portions 212, 214 and the respective collector portions 216, 218 through the first conductivity region 204 and the respective second conductivity region 206, 208. Second discharge currents, which may subsequently occur after the first discharge currents, may pass between the first conductivity region 204 and the respective third conductivity region 222, 224 through the respective second conductivity region 206, 208. The direction of the discharge current depends on the conductivity type of the respective regions.

In addition, although the device 200 includes a first segment 200a and a second segment 200b which are symmetrical mirror images of each other about a vertical axis A-A through the middle of the device 200, the device 200 may be modified such that it includes only either the first segment 200a or the second segment 200b.

Furthermore, the positioning of the regions and portions of the device 200 may be varied. For instance, the third conductivity region 222, 224 may be positioned anywhere between the respective collector portion 216, 218 and second conductivity region 206, 208, as long as at least a part of the second conductivity region 206, 208 remains in contact with the collector portion 216, 218. In one example, the third conductivity region 222, 224 may be disposed within only the collector portion 216, 218 and the second conductivity region 206, 208 (and not the isolation region 220). Alternatively, the third conductivity region 222, 224 may be disposed fully within the respective second conductivity region 206, 208.

In fact, the third conductivity region 222, 224 also need not be disposed partially within both the second conductivity region 206, 208 and the collector portion 216, 218. Instead, the third conductivity region 222, 224 may be disposed partially within only the second conductivity region 206, 208, or within only the collector portion 216, 218. In a non-limiting embodiment, the third conductivity region 222, 224 may even be disposed totally external of the second conductivity region 206, 208 and the collector portion 216, 218 (but this will cause the third conductivity region 222, 224 to occupy additional lateral and/or vertical space).

The first conductivity region 204, second conductivity region 206 and second conductivity region 208 may also be positioned differently. For example, one or more of the first conductivity region 204, second conductivity region 206 and second conductivity region 208 may be fully (instead of partially) disposed within the semiconductor body. The castellations of the first conductivity region 204, second conductivity region 206, second conductivity region 208 may be positioned differently from that shown in FIG. 2. For example, the spacing between the castellations of the first conductivity region 204 may be smaller or larger, and the castellations may be positioned closer or further away from the sides of the first conductivity region 204 and second conductivity regions 206, 208. The shapes and sizes of the tapered structures may also differ from those shown in FIG. 2. Further, each block layer 230 may fully overlap with the respective collector portion 216, 218 in a non-limiting embodiment. However, each block layer 230 need not be in contact with the respective collector portion 216, 218. Depending on the orientation of the device 200, each block layer 230 may be either above or below the respective collector portion 216, 218.

The depths of the first conductivity region 204, second conductivity region 206 and second conductivity region 208 may also be varied from each other. These depths need not be the same and the depth of each of the first conductivity region 204, second conductivity region 206 and second conductivity region 208 may be varied independently. Said differently, the first conductivity region 204 may be the same depth or a different depth from the second conductivity region 206 and/or the second conductivity region 208. Likewise, each of the second conductivity regions 206/208 may be the same or different depths from each other and/or the same or different depth from the first conductivity region 204.

The invention may be embodied in other specific forms without departing from the spirit or essential characteristics thereof. The foregoing embodiments, therefore, are to be considered in all respects illustrative rather than limiting the invention described herein. Scope of the invention is thus indicated by the appended claims, rather than by the foregoing description, and all changes that come within the meaning and range of equivalency of the claims are intended to be embraced therein.

1. An electrostatic discharge (ESD) protection device comprising:
a semiconductor body comprising a substrate;
a first conductivity region arranged at least partially within the semiconductor body;
a second conductivity region arranged at least partially within the semiconductor body; wherein the first conductivity region is laterally adjacent to the second conductivity region;
an emitter portion disposed in contact with the first conductivity region and arranged over the first conductivity region;
a collector portion disposed in contact with the second conductivity region and arranged over the second conductivity region; and
a third conductivity region disposed between the second conductivity region and the collector portion;
wherein the first conductivity region and the third conductivity region have a first conductivity type; wherein the second conductivity region, the emitter portion, and the collector portion have a second conductivity type; and wherein the first conductivity type is different from the second conductivity type; and
wherein the ESD protection device is configured to where a first discharge current passes between the emitter portion and the collector portion through the first conductivity region and the second conductivity region when an electrostatic discharge level exceeds a predetermined level; and a second discharge current subsequently occurs after the first discharge current and where the second discharge current passes between the first conductivity region and the third conductivity region through the second conductivity region.

2. The ESD protection device according to claim 1, wherein the third conductivity region comprises one or more dopants; and wherein the third conductivity region comprises a higher concentration of dopants as compared to the second conductivity region and the collector portion.

3. The ESD protection device according to claim 1, wherein the third conductivity region is disposed partially within one or both of the second conductivity region and the collector portion.

4. The ESD protection device according to claim 1, wherein the semiconductor body further comprises a fourth conductivity region, wherein the fourth conductivity region is arranged over the substrate, and wherein the fourth conductivity region comprises a first portion having the first conductivity type and a second portion having the second conductivity type.

5. The ESD protection device according to claim 4, wherein the first conductivity region and the second conductivity region are disposed at least partially within the first portion and the second portion of the fourth conductivity region respectively.

6. The ESD protection device according to claim 5, wherein the first portion of the fourth conductivity region extends laterally away from the first conductivity region towards the second conductivity region.

7. The ESD protection device according to claim 4, wherein the first portion of the fourth conductivity region is disposed within the second portion of the fourth conductivity region.

8. The ESD protection device according to claim 4, wherein the first portion of the fourth conductivity region comprises a high voltage well.

9. The ESD protection device according to claim 8, wherein the second portion of the fourth conductivity region comprises a deep well.

10. The ESD protection device according to claim 8, wherein the second portion of the fourth conductivity region comprises an epitaxial region and the second conductivity region is at least partially disposed within the epitaxial region.

11. The ESD protection device according to claim 10, wherein the second portion further comprises a buried layer arranged between the epitaxial region and the semiconductor substrate.

12. The ESD protection device according to claim 1, wherein the collector portion is disposed between the third conductivity region and a collector terminal for electrical connection of the collector portion to an external portion of the device.

13. The ESD protection device according to claim 1, wherein the semiconductor body comprises only the substrate; wherein the first conductivity region and the second conductivity region are at least partially arranged within the substrate.

14. The ESD protection device according to claim 1, further comprising:
a base portion having the first conductivity type where the base portion contacts the first conductivity region; and
a resistance between the emitter portion and the base portion.

15. The ESD protection device according to claim 1, wherein the first conductivity type is p-type and the second conductivity type is n-type.

16. The ESD protection device according to claim 1, wherein the first conductivity region is in contact with the second conductivity region.

17. The ESD protection device according to claim 1, further comprising an isolation region for isolating the emitter portion from the collector portion.

18. The ESD protection device according to claim 17, wherein the third conductivity region is disposed at least partially within the isolation region.

19. The ESD protection device according to claim 1, wherein the collector portion is arranged below a surface of the device; and wherein the device further comprises a block layer arranged over the surface of the device and the collector portion.

20. The ESD protection device according to claim 19, wherein the block layer at least partially overlaps the collector portion.
